(19) United States
(12) Patent Application Publication
(10) Pub. No.: US 2013/0140657 A1
(43) Pub. Date: Jun. 6, 2013

(54) MAGNETIC MEMORY DEVICES INCLUDING FREE MAGNETIC LAYER HAVING THREE-DIMENSIONAL STRUCTURE

(71) Applicants: Sung-chul LEE, Osan-si (KR); Kwang-seok KIM, Seongnam-si (KR); Kee-won KIM, Suwon-si (KR); Young-man JANG, Hwaseong-si (KR); Ung-hwan PI, Seoul (KR)

(72) Inventors: Sung-chul LEE, Osan-si (KR); Kwang-seok KIM, Seongnam-si (KR); Kee-won KIM, Suwon-si (KR); Young-man JANG, Hwaseong-si (KR); Ung-hwan PI, Seoul (KR)

(73) Assignee: SAMSUNG ELECTRONICS CO., LTD., Suwon-si (KR)

(21) Appl. No.: 13/572,105

(22) Filed: Aug. 10, 2012

(30) Foreign Application Priority Data
Dec. 5, 2011 (KR) 10-2011-0129158

(51) Int. Cl. H01L 29/82

(52) U.S. Cl. 257/421; 257/E29.323

(57) ABSTRACT

Magnetic memory devices including a free magnetic layer having a three-dimensional structure, include a switching device and a magnetic tunnel junction (MTJ) cell connected thereto. The MTJ cell includes a lower magnetic layer, a tunnel barrier layer, and a free magnetic layer, which are sequentially stacked. A portion of the free magnetic layer protrudes in a direction away from an upper surface of the tunnel barrier layer.

### CROSS-REFERENCE TO RELATED APPLICATIONS

This application claims the benefit of priority under 35 U.S.C. §119(e) from Korean Patent Application No. 10-2011-0129158, filed on Dec. 5, 2011, in the Korean Intellectual Property Office, the disclosure of which is incorporated herein in its entirety by reference.

### BACKGROUND

1. Field

Example embodiments relate to memory devices, and more particularly, to magnetic memory devices including a free magnetic layer having a three-dimensional structure.

2. Description of the Related Art

In the field of a magnetic tunnel junction (MTJ), a magnetic random access memory (MRAM) having a tunneling magnetoresistance (TMR) effect has been researched as one of the next generation of non-volatile memory devices due to its non-volatility, high-speed operation, and high endurance.

An initial MRAM uses a method of switching an MTJ by using an external magnetic field. Thus, a separate wiring in which current flows is required to generate an external magnetic field for switching an MTJ.

Considering high integration of a memory device, a separate wiring for generation of an external magnetic field may become a hindrance to the high integration of a magnetic memory device.

In the case of a spin transfer torque MRAM (STT-MRAM) for storing information by spin transfer torque of a spin current, which is recently introduced, an MTJ cell is switched according to a spin state of a current passing through the MTJ cell. Accordingly, no lead wire is needed to generate an external magnetic field, unlike in a conventional magnetic memory device. Thus, the STT-MRAM is evaluated as a magnetic memory device that meets the purpose of achieving a high integration.

It has been known that the thermal stability of an MTJ cell is related to an energy barrier (Eb) of a free magnetic layer.

It has been known that, when a free magnetic layer is a horizontal magnetic anisotropic material layer, if Eb/KBT (KB: Boltzmann constant, and T: absolute temperature) is about 60, the thermal stability of an MTJ cell is ensured for about 10 years. In general, although the feature size of a MTJ cell (i.e., the feature size of a free magnetic layer) varies according to the thickness of the free magnetic layer, the feature size of the free magnetic layer is 40 nm or more such that Eb/KBT is about 60.

The limited feature size of an MTJ cell may become a hindrance to the high integration of a magnetic memory device.

### SUMMARY

Example embodiments relate to memory devices, and more particularly, to magnetic memory devices including a free magnetic layer having a three-dimensional structure.

Provided are magnetic random access memories (MRAMs) that ensures high integration and thermal stability.

Additional aspects will be set forth in part in the description which follows and, in part, will be apparent from the description, or may be learned by practice of the presented example embodiments.

According to example embodiments, a magnetic memory device includes a switching device, and a magnetic tunnel junction (MTJ) cell connected to the switching device, wherein the MTJ cell includes a lower magnetic layer, a tunnel barrier layer, and a free magnetic layer, which are sequentially stacked, and wherein a portion of the free magnetic layer protrudes in a direction away from an upper surface of the tunnel barrier layer.

The free magnetic layer may include a first portion extending in a direction parallel to the upper surface of the tunnel barrier layer, and a second portion extending from a first end of the first portion in a direction perpendicular to the upper surface of the tunnel barrier layer.

The free magnetic layer may include a third portion extending from a second end of the first portion in the direction perpendicular to the upper surface of tunnel barrier layer.

A protrusion height of the second portion may be greater than a width of the first portion, which is measured in a short-axis direction. In this case, the protrusion height of the second portion of may be equal to or less than about 50 nm.

A protrusion height of each of the second and third portions may be greater than a width of the first portion, which is measured in a short-axis direction. In this case, the protrusion height of each of the second and third portions may be equal to or less than about 50 nm.

A thickness of each of the second portion and the third portion may be equal to or less than about 5 nm.

A size of the MTJ cell may be about 30 nm or less by about 15 nm or less.

The free magnetic layer may include a perpendicular or horizontal magnetic anisotropic material layer.

The free magnetic layer may include a perpendicular or horizontal magnetic anisotropic material layer. The free magnetic layer may be a CoFeB layer.

The tunnel barrier layer may be a MgO layer.

The lower magnetic layer includes a pinning layer, and a pinned layer that are sequentially stacked.

According to other example embodiments, a storage node of a magnetic memory device includes a lower magnetic layer, a tunnel barrier layer on the lower magnetic layer, and a free magnetic layer on the tunnel barrier layer, wherein a portion of the free magnetic layer protrudes in a direction away from an upper surface of the tunnel barrier layer.

In the storage node, the free magnetic layer may have the above-described properties.

In the magnetic memory device, the free magnetic layer of the storage node (MTJ cell) has a three-dimensional structure in which a portion of the free magnetic layer protrudes in an upper direction of the tunnel barrier layer. Thus, although a feature size of the storage node is equal to or less than about 30 nm, or equal to or less than about 20 nm, an effective feature size of the free magnetic layer may be equal to, or greater than, about 40 nm due to the protruding portion of the free magnetic layer. Accordingly, integration of the magnetic memory device is increased, and Eb/KBT is equal to, or greater than, about 60, thereby obtaining the thermal stability of the storage node.

### BRIEF DESCRIPTION OF THE DRAWINGS

These and/or other aspects will become apparent and more readily appreciated from the following description of the embodiments, taken in conjunction with the accompanying drawings of which:

FIG. 1 is a cross-sectional view of a magnetic memory device (MRAM) according to example embodiments;

FIG. 2 is a cross-sectional view of a magnetic tunnel junction (MTJ) cell of FIG. 1, according to example embodiments;

FIG. 3 is a perspective view for showing a three-dimensional structure of the MTJ cell of FIG. 1, according to example embodiments;

FIG. 4 is a cross-sectional view of the MTJ cell of FIG. 1, according to example embodiments; and

FIGS. 5 through 7 are graphs showing the result of a simulation about an energy barrier of an MTJ cell of a magnetic memory device according to example embodiments.

### DETAILED DESCRIPTION

Various example embodiments will now be described more fully with reference to the accompanying drawings in which some example embodiments are shown. However, specific structural and functional details disclosed herein are merely representative for purposes of describing example embodiments. Thus, the invention may be embodied in many alternate forms and should not be construed as limited to only example embodiments set forth herein. Therefore, it should be understood that there is no intent to limit example embodiments to the particular forms disclosed, but on the contrary, example embodiments are to cover all modifications, equivalents, and alternatives falling within the scope of the invention.

In the drawings, the thicknesses of layers and regions may be exaggerated for clarity, and like numbers refer to like elements throughout the description of the figures.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that, if an element is referred to as being “connected” or “coupled” to another element, it can be directly connected, or coupled, to the other element or intervening elements may be present. In contrast, if an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” if used herein, specify the presence of stated features, integers, steps, operations, elements and/or components, but do not preclude the presence or addition of one or more other features, integers, steps, operations, elements, components and/or groups thereof.

Spatially relative terms (e.g., “beneath,” “below,” “lower,” “above,” “upper” and the like) may be used herein for ease of description to describe one element or a relationship between a feature and another element or feature as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In order to more specifically describe example embodiments, various aspects will be described in detail with reference to the attached drawings. However, the present invention is not limited to example embodiments described.

Example embodiments relate to memory devices, and more particularly, to magnetic memory devices including a free magnetic layer having a three-dimensional structure.

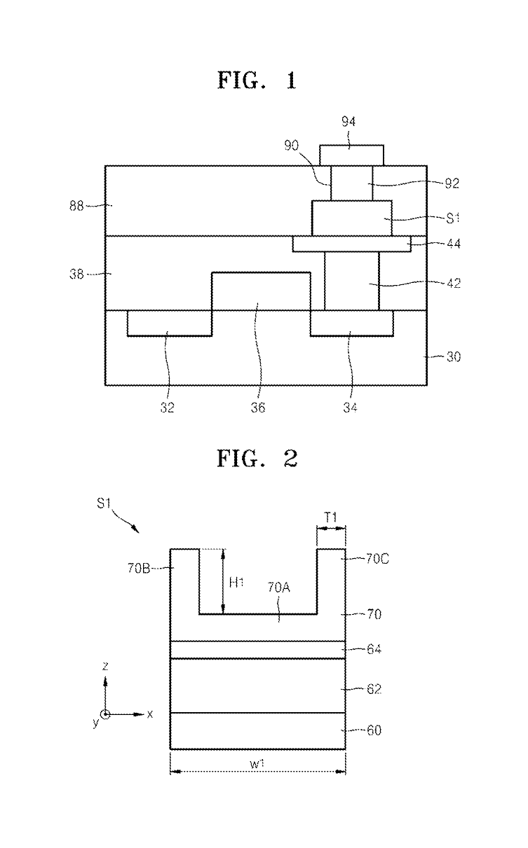

FIG. 1 is a cross-sectional view of a magnetic memory device (MRAM) according to example embodiments.

Referring to FIG. 1, first and second impurity regions 32 and 34 exist in a substrate 30 to separate from each other. The substrate 30 may be a semiconductor substrate or a substrate doped with impurities. One of the first and second impurity regions 32 and 34 may be a source region, and the other one may be a drain region. A gate deposition 36, including a gate electrode, is formed on the substrate 30 between the first and second impurity regions 32 and 34. The substrate 30, the first and second impurity regions 32 and 34, and the gate deposition 36 may constitute a field effect transistor (hereinafter, referred to as the transistor). The transistor is merely a kind of a switching device to be provided on the substrate 30. Another kind of a switching device, for example, a diode, may be provided instead of the transistor. A conductive plug 42 is formed on the second impurity region 34 to be separated from the gate deposition 36. A conductive pad layer 44 is provided on the conductive plug 42. The diameter of the conductive pad layer 44 may be greater than that of the conductive plug 42. The conductive pad layer 44 may be omitted. An interlayer insulation layer 38 is formed on the substrate 30 to surround the conductive plug 42 and the conductive pad layer 44. The first and second impurity regions 32 and 34 and the gate deposition 36 are covered with the interlayer insulation layer 38. The interlayer insulation layer 38 may be a general insulation material used for a semiconductor device. A storage node S1 is provided on the conductive pad layer 44. The storage node S1 may be a magnetic tunnel junction (MTJ) cell. The storage node S1 is covered by an interlayer insulating layer 88. The interlayer insulating layer 88 includes a via hole 90 that is formed therein so as to expose a portion of the storage node S1. The via hole 90 is filled with a conductive plug 92. A conductive layer 94 is formed on the interlayer insulating layer 88 so as to contact the conductive plug 92. The conductive layer 94 may be a bit line.

FIG. 2 is a cross-sectional view of an MTJ cell S1 of FIG. 1, according to example embodiments.

Referring to FIG. 2, the MTJ cell S1 includes a lower magnetic layer 60+62, a tunnel barrier layer 64, and a free magnetic layer 70. A capping layer (not shown) covering a surface of the free magnetic layer 70 may be further formed between the free magnetic layer 70 and the conductive plug 92. The lower magnetic layer 60+62 includes a pinning layer 60 and a pinned layer 62 that are sequentially stacked. The lower magnetic layer 60+62 may further include at least one material layer, for example, a buffer layer that is formed below the pinning layer 60. The pinning layer 60 may be a magnetic layer having a given thickness, for example, a CoFe layer. The thickness of the pinning layer 60 may be equal to, or less than, about 10 nm. The pinned layer 62 may be a magnetic layer having a desired thickness, for example, a CoFeB layer having a desired thickness. The thickness of the pinned layer 62 may be equal to, or less than, about 10 nm. The pinning layer 60 and the pinned layer 62 may have opposite magnetization directions. A metal layer (not shown) may be formed between the pinning layer 60 and the pinned layer 62. The metal layer may be, for example, ruthenium (Ru) layer. The thickness of the metal layer may be equal to, or less than, about 5 nm. The tunnel barrier layer 64 may be an oxide layer having a desired thickness, for example, a MgO layer. The thickness of the tunnel barrier layer 64 may be equal to, or less than, about 5 nm. The free magnetic layer 70 may have a three-dimensional structure, unlike the lower material layers 60, 62, and 64. In detail, the free magnetic layer 70 includes a first portion 70A formed in parallel to the tunnel barrier layer 64 and second and third portions 70B and 70C that are formed perpendicular to the tunnel barrier layer 64. The second and third portions 70B and 70C are portions that protrude from two ends of the first portion 70A in an upward direction of the tunnel barrier layer 64. The second and third portions 70B and 70C may be spaced apart from each other and may be formed in parallel to each other. Protrusion heights (H1) of the second and third portions 70B and 70C, which are measured from an upper surface of the first portion 70A, may be the same. Alternatively, the protrusion heights (H1) of the second and third portions 70B and 70C may be different from each other. The protrusion heights (H1) of the second and third portions 70B and 70C may be equal to, or less than, for example, about 50 nm, and for example, may be from about 20 nm to about 30 nm. The first through third portions 70A, 70B, and 70C may have the same thickness. Alternatively, the thickness of the first portion 70A may be different from the thickness T1 of each of the second and third portions 70B and 70C. The thickness T1 of each of the second and third portions 70B and 70C may be equal to, or less than, for example, about 5 nm, and for example, may be equal to, or less than, about 3 nm. The thickness T1 of each of the second and third portions 70B and 70C may be determined in consideration of a width W1 measured in an x-axis direction of the MTJ cell S1. Alternatively, the second and third portions 70B and 70C may have different thicknesses. The free magnetic layer 70 may be a horizontal or perpendicular magnetic anisotropic material layer. When the free magnetic layer 70 is a perpendicular magnetic anisotropic material layer, the free magnetic layer 70 may be a material layer having interface perpendicular magnetic anisotropy (IPMA). The free magnetic layer 70 may be, for example, a CoFeB layer having a desired thickness.

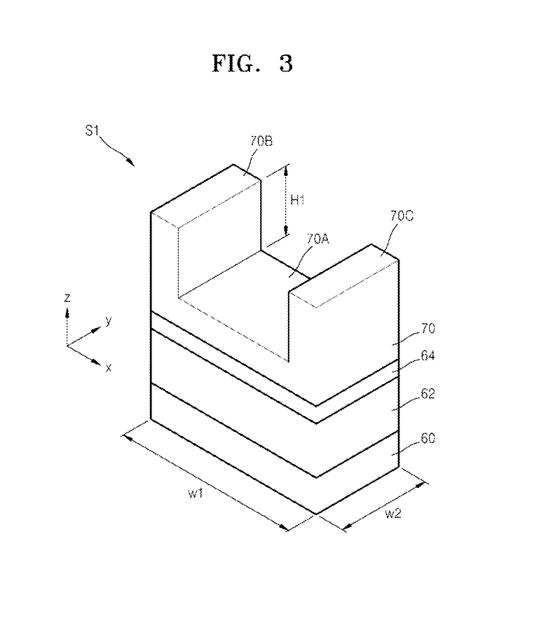

FIG. 3 is a perspective view for showing a three-dimensional structure of the MTJ cell S1 of FIG. 1, according to example embodiments.

Referring to FIG. 3, the free magnetic layer 70 including the first through third portions 70A, 70B, and 70C may have a ‘U’ shape. A height of each of the second and third portions 70B and 70C, which is measured in a y-axis direction, may be the same as a width w2 of the MTJ cell S1, which is measured in a y-axis direction. A width of the first portion 70A, which is measured in a long-axis direction (x-axis direction) may be the same as a width w1 of the MTJ cell S1, which is measured in an x-axis direction. The width w1 of the MTJ cell S1, which is measured in an x-axis direction, may be greater than a width w2 of the MTJ cell S1, which is measured in a y-axis direction. For example, the width w1 in an x-axis direction may be less than (about) 40 nm and may be equal to, or less than, (about) 30 nm, or equal to, or less than, (about) 20 nm. In addition, the width w2 in a y-axis direction may be equal to, or less than, for example, (about) 20 nm and may be equal to, or less than, (about) 15 nm, or equal to, or less than, (about) 10 nm. Because the feature size of the MTJ cell S1 is smaller than (about) 40 nm, integration of a magnetic memory device may be increased compared to a typical magnetic memory device. The protrusion height H1 of each of the second and third portions 70B and 70C of the free magnetic layer 70 may be greater than the width w2 of the MTJ cell S1, which is measured in a y-axis direction. The width w2 of the MTJ cell S1, which is measured in a y-axis direction, may be the same as a width of the first portion 70A of the free magnetic layer 70, which is measured in a short-axis direction (y-axis direction). Thus, a relationship between the first portion 70A, and the second and third portions 70B and 70C of the free magnetic layer 70 may be defined according to Inequality (1) below.

H1/w2>1 (1)

When Inequality (1) is satisfied, the protrusion height H1 of each of the second and third portions 70B and 70C of the free magnetic layer 70 may exceed the above-described numerical range.

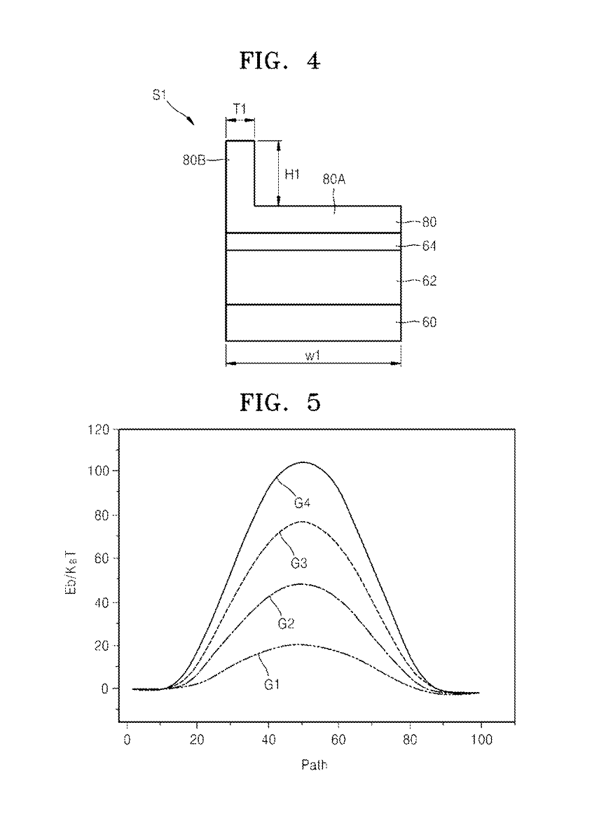

FIG. 4 is a cross-sectional view of the MTJ cell S1 of FIG. 1, according to example embodiments.

Referring to FIG. 4, a free magnetic layer 80 may have a three-dimensional structure including first and second portions 80A and 80B. The first portion 80A is formed in parallel to the tunnel barrier layer 64. The second portion 80B is formed perpendicular to the first portion 80A and protrudes in an upper direction of the tunnel barrier layer 64. The second portion 80B may be connected to a left lateral end portion of the first portion 80A, or alternatively may be connected to a right lateral end portion of the first portion 80A. The first portion 80A may correspond to the first portion 70A of the free magnetic layer 70 of FIG. 3. In addition, the second portion 80B may correspond to the second portion 70B, or the third portion 70C of the free magnetic layer 70 of FIG. 3.

FIGS. 5 through 7 are graphs showing the result of a simulation about an energy barrier of an MTJ cell of a magnetic memory device, according to example embodiments.

FIG. 5 shows a change in energy barrier according to a switching path when a size of the MTJ cell is 20 nm*10 nm and the thickness of the first portion 70A of the free magnetic layer 70 is 2.4 nm.

In FIG. 5, first through fourth plots G1, G2, G3, and G4 show a change in energy barrier according to a switching path when the protrusion height H1 of each of the second and third portions 70B and 70C of the free magnetic layer 70 is 14.4 nm, 22.4 nm, 30.4 nm, and 38.4 nm, respectively.

Referring to FIG. 5, in the center of the switching path, Eb/KBT is equal to or greater than 60, between the second and third plots G2 and G3. It is confirmed that the protrusion height H1 of each of the second and third portions 70B and 70C needs to be greater than 22.4 nm such that an energy barrier is equal to, or greater than, (about) 60.

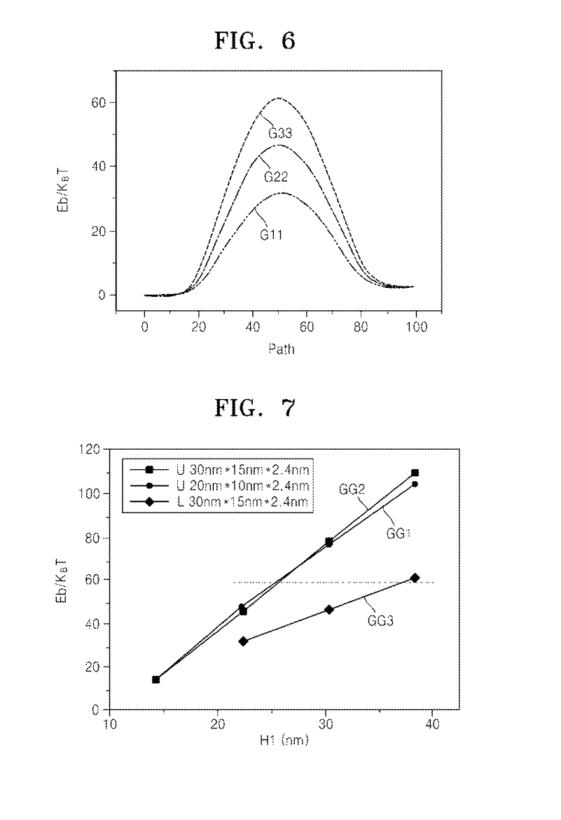

FIG. 6 relates to the MTJ cell of FIG. 4 and shows a change in energy barrier according to a switching path when a size of the MTJ cell is 30 nm*15 nm and the thickness of the first portion 80A of the free magnetic layer 80 is 2.4 nm.

In FIG. 6, first through third plots G11, G22, and G33 show a change in energy barrier according to a switching path when the protrusion height H1 of the second portion 80B of the free magnetic layer 80 is 22.4 nm, 30.4 nm, and 38.4 nm, respectively.

Referring to FIG. 6, in the center of the switching path, a case where Eb/KBT is equal to, or greater than, (about) 60 is exhibited on the third graph G33. It is confirmed that the protrusion height H1 of the second portion 80B needs to be greater than 30.4 nm such that an energy barrier is equal to, or greater than, (about) 60.

FIG. 7 is graph showing a change in energy barrier according to the protrusion heights H1 of the free magnetic layers 70 and 80, according to example embodiments.

In FIG. 7, a first graph GG1 relates to the MTJ cell of FIG. 2 including the free magnetic layer 70 having a ‘U’ shape and shows a change in energy barrier according to the protrusion heights H1 of the second and third portions 70B and 70C of the free magnetic layer 70 when a size of the MTJ cell is 20 nm×10 nm and the thickness of the first portion 70A of the free magnetic layer 70 is 2.4 nm. A second graph GG2 relates to the MTJ cell of FIG. 2 and shows a change in energy barrier according to the protrusion heights H1 of the second and third portions 70B and 70C of the free magnetic layer 70 when a size of the MTJ cell is 30 nm×15 nm and the thickness of the first portion 70A of the free magnetic layer 70 is 2.4 nm. A third graph GG3 relates to the MTJ cell of FIG. 4 including the free magnetic layer 80 having a ‘L’ shape and shows a change in energy barrier according to the protrusion height H1 of the second portion 80B of the free magnetic layer 80 when a size of the MTJ cell is 30 nm×15 nm and the thickness of the first portion 80A of the free magnetic layer 80 is 2.4 nm.

Referring to the first through third plots GG1 through GG3, with regard to the first and second plots GG1 and GG2, it may be confirmed that, when the extrusion height H1 is equal to, or greater than, (about) 26 nm, Eb/KBT is equal to, or greater than, (about) 60. In addition, with regard to the third plot GG3, it may be confirmed that, when the extrusion height H1 is equal to, or greater than, (about) 38 nm, Eb/KBT is equal to, or greater than, (about) 60.

From the result, with regard to the MTJ cells of FIGS. 2 and 4, it may be confirmed that, when the protrusion height H1 of the free magnetic layers 70 and 80 is equal to, or greater than, a given value, the thermal stabilities of the MTJ cells may be ensured.

It should be understood that the example embodiments described herein should be considered in a descriptive sense only and not for purposes of limitation. Descriptions of features or aspects within each example embodiment should typically be considered as available for other similar features or aspects in other example embodiments.

What is claimed is:

1. A magnetic memory device, comprising:
a switching device; and
a magnetic tunnel junction (MTJ) cell connected to the switching device,
wherein the MTJ cell includes a lower magnetic layer, a tunnel barrier layer, and a free magnetic layer, which are sequentially stacked, and
wherein a portion of the free magnetic layer protrudes in a direction away from an upper surface of the tunnel barrier layer.

2. The magnetic memory device of claim 1, wherein the free magnetic layer includes,
a first portion extending in a direction parallel to the upper surface of the tunnel barrier layer, and
a second portion extending from a first end of the first portion in a direction perpendicular to the upper surface of the tunnel barrier layer.

3. The magnetic memory device of claim 2, wherein a protrusion height of the second portion is greater than a width of the first portion, which is measured in a short-axis direction.

4. The magnetic memory device of claim 3, wherein the protrusion height of the second portion of is equal to or less than about 50 nm.

5. The magnetic memory device of claim 2, wherein the free magnetic layer includes a third portion extending from a second end of the first portion in the direction perpendicular to the upper surface of the tunnel barrier layer.

6. The magnetic memory device of claim 5, wherein a protrusion height of each of the second and third portions is greater than a width of the first portion, which is measured in a short-axis direction.

7. The magnetic memory device of claim 6, wherein the protrusion height of each of the second and third portions is equal to or less than about 50 nm.

8. The magnetic memory device of claim 5, wherein a thickness of each of the second portion and the third portion is equal to or less than about 5 nm.

9. The magnetic memory device of claim 1, wherein a size of the MTJ cell is about 30 nm or less by about 15 nm or less.

10. The magnetic memory device of claim 1, wherein the free magnetic layer includes a perpendicular or horizontal magnetic anisotropic material layer.

11. The magnetic memory device of claim 1, wherein the free magnetic layer is a CoFeB layer.

12. The magnetic memory device of claim 1, wherein the tunnel barrier layer is a MgO layer.

13. The magnetic memory device of claim 1, wherein the lower magnetic layer includes a pinning layer, and a pinned layer that are sequentially stacked.

14. A storage node of a magnetic memory device, the storage node comprising:
a lower magnetic layer;
a tunnel barrier layer on the lower magnetic layer; and
a free magnetic layer on the tunnel barrier layer,
wherein a portion of the free magnetic layer protrudes in a direction away from an upper surface of the tunnel barrier layer.

15. The storage node of claim 14, wherein the free magnetic layer includes,
a first portion extending in a direction parallel to the upper surface of the tunnel barrier layer, and
a second portion extending from a first end of the first portion in a direction perpendicular to the upper surface of the tunnel barrier layer.

16. The storage node of claim 15, wherein the free magnetic layer includes a third portion extending from a second end of the first portion in the direction perpendicular to the upper surface of the tunnel barrier layer.

17. The storage node of claim 16, wherein a protrusion height of each of the second and third portions is greater than a width of the first portion, which is measured in a short-axis direction.

18. The storage node of claim 17, wherein the protrusion height of each of the second and third portions is equal to or less than about 50 nm.

19. The storage node of claim 16, wherein protrusion heights of the second and third portions are the same.

20. The storage node of claim 16, wherein a thickness of each of the second portion and the third portion is equal to or less than about 5 nm.

21. The storage node of claim 15, wherein a protrusion height of the second portion is greater than a width of the first portion, which is measured in a short-axis direction.

22. The storage node of claim 21, wherein the protrusion height of the second portion of is equal to or less than about 50 nm.

23. The storage node of claim 14, wherein the free magnetic layer includes a perpendicular or horizontal magnetic anisotropic material layer.
